(19) United States
(12) Patent Application Publication
(10) Pub. No.: US 2008/0216747 A1
(43) Pub. Date: Sep. 11, 2008

(54) Coating Installation And Gas Piping

(75) Inventors: Stephan Wieder, Frankfurt (DE); Tobias Repmann, Alzenau (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/849,524

(22) Filed: Sep. 4, 2007

Related U.S. Application Data
(60) Provisional application No. 60/892,999, filed on Mar. 5, 2007.

(30) Foreign Application Priority Data
Mar. 5, 2007 (EP) 07103473.0

(51) Int. Cl. C23C 16/00

(52) U.S. Cl. 118/723 R; 118/715

(57) ABSTRACT

A coating installation coating installation includes a process chamber and a gas line system for supplying a gas into the process chamber. The gas line system has at least one feed opening for feeding gases into the gas line system and outlet openings for letting the gas out of the gas line system. Lines are each arranged between the feed opening(s) and the outlet openings. The flow resistance of the lines between the at least one feed opening and the outlet openings is essentially equally large. The gas line system has at least one branch point at which a first line section opens into at least three second line sections connected to the first line section. The first and second line sections are arranged in different levels and branch out like a tree structure. The line sections may be milled as a recess and/or depression in plates.

### CROSS-REFERENCES TO RELATED APPLICATIONS

This application is a non-provisional, and claims the benefit, of commonly assigned U.S. Provisional Application No. 60/892,999, filed Mar. 5, 2007, entitled “Coating Installation And Gas Piping” and European Patent Application No. EP 07103473.0, filed Mar. 5, 2007, entitled “Coating Installation And Gas Piping,” the entirety of each of which are herein incorporated by reference for all purposes.

### TECHNICAL FIELD

The invention concerns a coating installation, for example a PECVD coating installation, comprising a process chamber, and a gas line system for the feeding and/or outlet of a gas into or out of the process chamber, wherein the gas line system has at least one feed opening for feeding gas into the gas line system or for removing gas from the gas line system, at least two outlet openings for letting out the gas from the gas line system or for introducing the gas into the gas line system, as well as lines, which are each arranged between at least the one feed opening and the outlet openings, with the lines being formed such that the flow resistance of the lines between the at least one feed opening and the outlet openings is essentially equally large in each case. Furthermore, the invention concerns a gas line system for supplying and/or letting out a gas into or out of a process chamber of a coating installation, especially a PECVD coating installation, comprising at least one feed opening for feeding gas into the gas line system or for removing gas from the gas line system, at least two outlet openings for letting out the gas from the gas line system or for introducing the gas into the gas line system, and lines, which are each arranged between the at least one feed opening and the outlet openings, with the lines being formed such that the flow resistance of the lines between the at least one feed opening and the outlet openings is essentially equally large in each case.

### BACKGROUND OF THE INVENTION

A plurality of coating processes are available for the coating of substrates. One of these methods, which is used, for example, in the production of solar cells, is the so-called PECVD (Plasma Enhanced Chemical Vapor Deposition) method, in which the coating takes place from the gaseous phase with the aid of plasma. In such a method, gases are supplied to a process or plasma chamber. The plasma of these supplied gases contains the layer-forming pre-products, which facilitate layer growth on a substrate.

In order that homogeneous coatings may be achieved, the process gas must be supplied to the process chamber or the plasma chamber as homogeneously as possible. Ways are known from the prior art of achieving homogeneous gas supply to a PECVD process chamber. For example, a gas line is provided that supplies a so-called “showerhead” electrode with a suitable mixture of the process gas. The “showerhead” electrode serves on one hand as a first electrode, which can form a plasma by means of a second electrode. On the other, it has outlet openings, through which the process gas flowing in via the gas line is supplied homogeneously to the process chamber, i.e. the process gas is distributed homogeneously onto or over the coating surface. Such a “showerhead” electrode for the coating of a circular substrate is described, for example, in U.S. Pat. No. 6,410,089 B 1.

In addition, it is possible to distribute the process gas with the help of a line structure. The gas is distributed from a feed point via a branching line structure. As shown in FIG. 1, the process gas can be fed into the gas line system via a feed point 2. The fed-in process gas is split uniformly in two directions onto lines 3a and 3b. The gas is supplied to the process chamber via outlet openings 4a and/or 4b. Process gas is admitted through the first opening 4a to a first quadratic sector 5a, which is marked with dashed lines. A second sector 5b is supplied with process gas through the second opening 4b. In order that a homogeneous supply may be obtained, the flow resistances of the lines 3a and 3b are equally large within given tolerances.

In order that a larger area may be covered by the admitted gas, the gas supplied by way of a punctiform feed opening 2, as outlined in FIG. 2, can first be split two-fold by two first line sections 3a and 3b. The end of the line sections 3a and 3b can each in turn be regarded as virtual feed point 2a or 2b, from which, in each case, two further line sections 3aa and 3ab or 3ba and 3bb proceed.

The branch points 2a and 2b can also be regarded as real feed points if they physically form a passage into another channel, from where the structure is continued.

The outcome is that the same quantity of gas is admitted to each of the four sectors 5a, 5b, 5c and 5d, so that the quadratic area shown in FIG. 2 has an overall adequately homogeneous supply of process gas.

Projected onto a two-dimensional illustration, the gas-distribution system consists, in accordance with FIG. 2, of an H-shaped structure, with process gas being fed into the center of the H-structure and supplied to the process chamber at the four corner points of the H-structure. Of course, a further branching level, again with an H-shaped line structure, for example, can be supplied via the corner points. In this way, any number of desired branching levels can be provided, depending upon size and homogeneity requirements. For even distribution of the gas in the plasma chamber above the substrate, the conductance values of the line sections between starting point and end point within anyone distribution level are each identical. This can be achieved, for example, with corresponding lines having geometrically the same design, i.e. corresponding line sections have the same length and same cross-section. Each line branches out on transition from one level to the next into the same number of lines, so that no measures are necessary for keeping the flow resistance between the central feed point and each of the outlet points constant. Altogether, then, a line structure results, which runs into different levels and opens from one feed point into 21½ (n=1, 2, 3 . . . ) new feed points.

A structure having H-like two-way and four-way branching is disclosed, for example, in DEI 0045958 AI, which is incorporated herein by reference for all purposes.

Since the (virtual or real) feed points 2; 2a, 2b (see FIG. 2) and the corresponding outlet points 4a, 4b, 4c and 4d form a regular raster in each level, areas with an aspect ratio of 1:1, or, if only one half of an H-structure is realized, with an aspect ratio of 2:1, can be supplied homogeneously with process gas (in the latter case, the H-structure is cut along the vertical symmetry axis) in the case of the known line structures. Beyond that, for example, rectangular coating formats with an aspect ratio of 4:1, but at any rate only with an even-numbered aspect ratio, are conceivable.

Regular rasters with a single central feed point, with which surfaces having non-even-numbered aspect ratio can be homogeneously coated, cannot be realized with the help of these structures, however.

### BRIEF SUMMARY OF THE INVENTION

A coating installation or gas line system is provided for a coating installation with which, in a process/plasma chamber, homogeneous process gas distribution can be obtained over the surface of a substrate for different substrate formats and thus homogeneous coating of the substrate can be obtained. Especially, rectangular substrate formats having aspect ratios other than even-numbered ones shall be capable of being uniformly supplied via a central feed and a regular raster of gas outlet points.

The inventive coating installation, especially a PECVD coating installation, comprises a process chamber, and a gas line system for supplying and/or letting out a gas into or out of the process chamber of the coating installation, with the gas line system having at least one feed opening for feeding gas into the gas line system or for removing gas from the gas line system, at least two outlet openings for letting out the gas from the gas line system or for introducing the gas into the gas line system, and lines, which are each arranged between the at least one feed opening and the outlet openings, with the lines being formed such that the flow resistance of each line between the at least one feed opening and the outlet openings is essentially equally large. The gas line system has at least one branch point, at which a first line section opens into at least three second line sections connected to the first line section.

In order that a ratio deviating from even-numbered aspect ratios such as 1:1 or 2:1 of a rectangular substrate may be realized, the invention provides for branching in at least one distribution level from a virtual or real gas feed point into more than two lines, especially directly into three lines. Uniform gas distribution is ensured by the fact that the gas conductance values of the branched line sections are equally large within each distribution level. The conductance values of one level may then only deviate from each other within given tolerances if the conductance values are very large (and thus negligible) relative to the conductance values of one or several other distribution levels. All paths between the feed opening and the outlet openings have a similar configuration, i.e. a similar cross-sectional profile along their length. Thus, the flow characteristics through all branches of the tree structure are so similar that no additional measures need be adopted for adjusting flow resistances to each other. Such an adjustment is anyway difficult to calculate and manufacture. At any rate, homogeneous gas outflow from the outlet openings, for example, may be ensured, i.e. the gas must flow from all outlet openings at the same flow rate (per unit of time), with the same current profile, at the same speed, etc.

By means of the invention, odd-numbered formats (except 1:1), especially, with aspect ratios of 3:2, 3:4 etc. can also be homogeneously coated, with a regular raster of outlet openings being supplied from a single feed point. For example, the structure is thereby symmetrical to the extent that all lines or paths between the feed point and the outlet openings have the same length, an identical number of branches, and the same cross-sectional profile. Especially, the line sections branched at the branch point can proceed at the same angles from the line section on the feed-opening side, i.e. the change of direction of the through-flowing gas at the branch point must take place at the same angle as the gas flowing through the branched line sections. In this way, identical flow resistance is obtained in the lines of one line level.

One way to distribute the gas in a process chamber over a surface with an aspect ratio of 3:2 consists, for example, in dividing the rectangular substrate surface into, for example, six quadratic surfaces, which are each supplied centrally via outlet openings in the center of the squares. The outlet openings can be supplied uniformly from the central feed point for supplying the total surface by arranging for two-way and three-way divisions, which are point-symmetrical with the centre of the total surface.

The inventive coating installation can be used particularly advantageously in a PECVD coating process, for example for the production of thin-layer silicon solar modules. With the PECVD method, the silicon layers of the solar cell are deposited onto a flat glass substrate. The size of the glass usually corresponds to the size of the solar modules. For various reasons, it is desirable to make modules with aspect ratios other than 1:1 or 2:1. The coating installation proposed in this application reflects this. The advantages of providing rectangular modules having non-even-numbered aspect ratios consist on the one hand in better handling of these formats relative to quadratic modules, e.g. during installation of solar modules. In addition, modules integrated into buildings usually have rectangular formats, and especially formats with aspect ratios other than 2:1. A further advantage of non-even-numbered aspect ratios consists in the higher homogeneity of the coating in PECVD methods. Since problems with the homogeneity of the coating arise when the electrode is long, choosing an aspect ratio of 3:2 instead of, for instance, 2:1, is more favorable for the same coating area. Ultimately, the 3:2 format is also a widespread image format, which is practically common or becoming standard.

In all circumstances, the invention makes available a regular raster for feeding gas into the plasma chamber combined with simultaneous uniform distribution of the gas to form a homogeneous coating.

The first line section flows especially into exactly three second line sections connected to the first line section. Overall, a tree structure forms with branches into different levels (the levels can be regarded either concretely as layer arrangements or as abstract branching levels), i.e. the lines keep branching out toward the outlet openings. The branching line sections are thereby in such mirror symmetry and/or in point symmetry with the branch point that different flow resistances do not arise in the line branches.

Conversely, the gas line system can naturally also be used as a system for extracting gas from the process chamber. This possibility is also to be protected in the context of the invention, even if it is not always described in detail. The outlet openings leading into the process chamber then serve as openings for extracting the gas from the process chamber. The extracted gas passes via the line system to the central opening, designated feed opening (in the context of this application), via which it leaves the gas line system.

Connected to the at least one feed opening are preferably at least three outlet openings, especially exactly three outlet openings or a multiple of three outlet openings. In this way, rectangular formats with odd-numbered aspect ratios can be homogeneously coated through the provision of a regular supply raster.

Especially, the lines between the feed opening and the outlet openings are of the same length. At least the lines in one level of large flow resistance are to have the same length, at least starting from the three-way division at a branching or node. The same length then leads essentially to equally large flow resistance, at least in the three-way divided structure. The invention is particularly suitable for systems in which flow resistance is not so large in any level that the flow resistance in the other levels would be negligible by comparison.

The lines each have the same number of branches, preferably between the feed opening and the outlet openings.

The lines can run into at least two levels. This creates a tree structure with different levels, with the term “level” capable of being interpreted abstractly or concretely. Proceeding from the central feed opening, the line structure branches out at any rate between two levels into three line sections at each node. The branching or nodes are located at the transition from one level to the next.

The first line section can run from a first point, especially the feed point, to the branch point, and the at least three following second line sections, proceeding from the branch point, can form angles of 90° and/or 180° among themselves.

The three line sections proceeding from the branch point can form angles of 45°, 135° or 225° with the first line section.

The line system preferably has a symmetrical structure, at least in one level. Especially, the branching lines are-formed so as to be point-symmetrical with the branching or node.

At least one line section can be formed as a recess and/or depression in a plate, especially by milling. Especially, one or more line levels can each be milled into a plate. The plates are arranged above each other like a sandwich, such that a three-dimensional tree structure develops.

The first line section is preferably formed, especially milled, as a recess and/or depression in a plate, and a connection is formed as a drill hole in the plate between the first line section and the at least three second line sections arranged on the side of the plate facing away from the first line section. The line sections milled into the plates are thus connected to the line sections of other levels by drill holes in the plates.

The outlet openings are especially arranged as a regular raster over a total area such that the outlet openings each form centers for contiguous squares each of the same area, with the total area forming a rectangle with sides of unequal length and a non-even-numbered side-length ratio. For example, with the exception of a square (where V=I), ratios V of V=(3*2ⁿ)/(2^{m}) where n=0, 1, 2, 3 . . . and m=0, 1, 2, 3, . . . e.g. 3:1, 3:2, 3:4, 6:1, etc. are to be realized in the context of the invention. That is, where n and/or m are any positive integer.

The number of outlet openings in a preferred embodiment is three or an integral multiple of three. Thus, uniform gas supply is possible to a number of squares divisible by three. This corresponds to the possibility of a non-even-numbered aspect ratio. The number N is N=3*2ⁿ, where n=0, 1, 2, 3 . . . .

The gas line system is formed preferably in the cover or as the cover of the process chamber of the coating installation.

Within the process chamber, means can be arranged for the generation of a plasma, e.g. electrodes.

The outlet openings that open into the process chamber can be formed as openings in a plasma-generating electrode. In other words, at least that level of the gas line system which contains the outlet openings can be formed as the flat electrode of a PECVD system. Together with another electrode, it can form a plasma in the process chamber.

The task is also achieved by the provision of a gas line system for supplying and/or letting out a gas into or out of a process chamber of a coating installation, especially a PECVD coating installation, comprising at least one feed opening for feeding gas into the gas line system and/or for removing gas from the gas line system, at least two outlet openings for letting out the gas from the gas line system or for the introduction of the gas into the gas line system, and lines that are each arranged between the at least one feed opening and the outlet openings in each case, with the lines being formed such that the flow resistance of the lines between the at least one feed opening and the outlet openings is essentially equally large in each case. The gas line system has at least one branch point, at which a first line section flows into at least three second line sections connected to the first line section.

The gas line system can, in the context of the invention, also be a subsystem of a larger system. The invention refers in principle to 3-way branches in the generic gas line system for supplying a number of three openings (or multiples thereof).

Ratios are always to be indicated with the larger side length in the numerator and the smaller side length in the denominator. All statements in the case of inverted aspect ratios are naturally to fall under the content of this application in the same way.

The characteristics described in connection with the coating installation are also to be claimed with regard to the gas line system, which represents a component of the inventive coating system. In addition, all possible combinations of the described characteristics are to be claimed in the context of this invention.

### BRIEF DESCRIPTION OF THE DRAWINGS

Further characteristics, features and advantages of the present invention are apparent from the following description of special embodiments.

FIG. 1 is a plan view of a line system in accordance with the prior art, projected schematically onto a two-dimensional illustration.

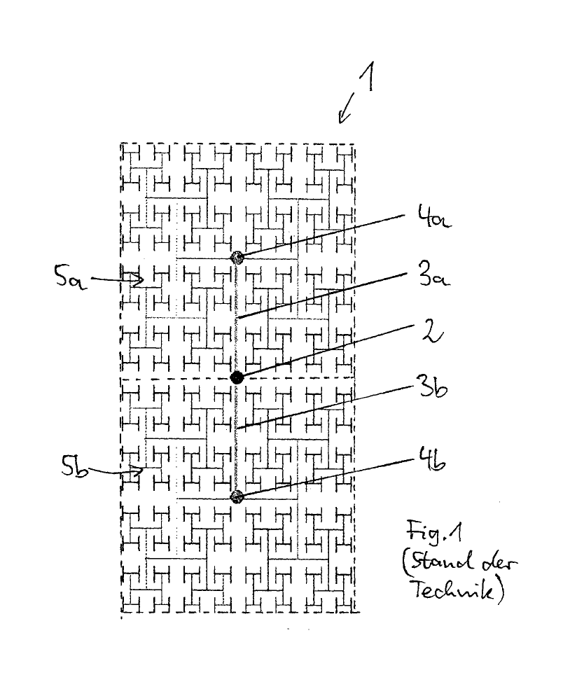

FIG. 2 is a plan view of a further line system in accordance with the prior art, projected schematically onto a two-dimensional illustration.

FIG. 3 is a plan view of a first embodiment of the gas line system, in accordance with the invention projected schematically onto a two-dimensional illustration.

FIG. 4 is a schematic plan view of a second embodiment of the gas line system, in accordance with the invention projected onto a two-dimensional illustration.

### DETAILED DESCRIPTION OF THE INVENTION

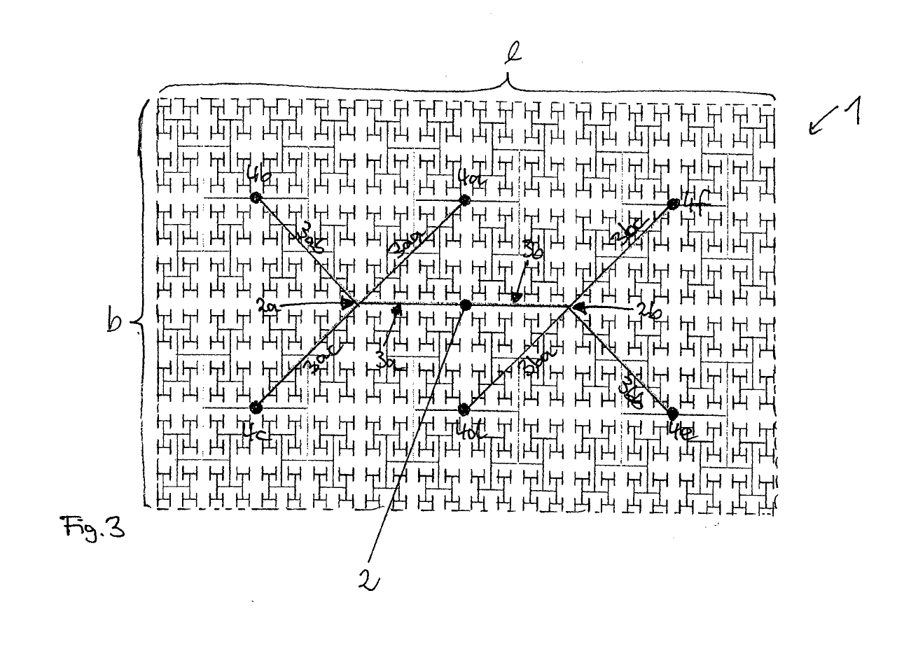

FIG. 3 shows a first embodiment of a gas line system 1 for a PECVD The coating installation in accordance with the invention. A two-stage distribution system is sketched in this connection.

The process gas is supplied via a central feed opening 2. At a first node, the supplied gas divides equally into two lines 3a and 3b, which essentially have identical flow resistance as far as two (virtual or real) feed points 2a or 2b.

At each of the virtual feed points 2a and 2b is formed a 3-way branch. The 3-way branches are implemented in a level below the level of the lines 3a and 3b.

The corresponding line sections proceeding from the nodes 2a or 2b are labeled with the reference symbols 3aa, 3ab, 3ac or 3ba, 3bb, 3bc. They connect the branching points 2a or 2b with outlet openings 4a, 4b and 4c or 4d, 4e and 4f.

At the branching points 2a and 2b, the line sections 3aa, 3ab, 3ac or 3ba, 3bb, 3bc open, relative to the line sections 3a or 3b, at angles of 45°, 135° or 225° (thus at 90° angles among themselves), towards the outlet openings 4a, 4b and 4c or 4d, 4e and 4f.

These line sections 3aa, 3ab, 3ac, 3ba, 3bb or 3bc have the same flow resistances between the branching points 2a or 2b and the respective outlet points 4a, 4b, 4c, 4d, 4e or 4f. In this way, it is ensured that same quantities of gas flow out from each of the outlet points 4a, 4b, 4c, 4d, 4e and 4f. The gas is thus admitted sufficiently homogeneously to the total area marked by dashed lines and by the base raster, since each of the gas outlet openings 4a, 4b, 4c, 4d, 4e and 4 forms the center of the quadratic sector occupying 1/61 h of the total area.

However, the points 4a, 4b, 4c, 4d, 4e and 4f, instead of opening as outlet openings into the plasma chamber, can again be virtual or real feed points or feed openings that uniformly supply gas to a further connecting line structure, which in certain circumstances may be arranged in a further level. It goes without saying that, in each level, the flow resistance between the virtual or the real feed points and the outlet points or outlet openings is essentially equally large.

In the present embodiment, the lines 3a, 3b or 3aa, 3ab, 3ac, 3ba, 3bb, 3bc are each milled into a plate, with the plates of the lines 3a, 3b or 3aa, 3ab, 3ac, 3ba, 3bb, 3bc forming a tree structure in two levels arranged one above the other. The central feed point 2 is formed as a passage 2 in a cover plate covering the first line level 3a, 3b in order that entry to the line system 3a, 3b may be facilitated. The (real or virtual) feed points 2a and 2b are designed as passages 2a, 2b by the plate having the line structure 3a, 3b in order that a transition may be made to the line system 3aa, 3ab, 3ac, 3ba, 3bb, 3bc of the second line level. The outlet openings 4a, 4b, 4c, 4d, 4e and 4f are formed as passages in the plate in which the second line level 3aa, 3ab, 3ac, 3ba, 3bb, 3bc is milled. In this way, a sandwich-like plate structure with connecting openings between the individual levels is created.

The complete line structure with tree-like branching lines for the uniform distribution of the gas to the outlet openings 4a, 4b, 4c, 4d, 4e and 4f can be formed as a cover plate of a process chamber. In this case, the process gas is introduced into the process chamber homogeneously and uniformly from the top via the level to be coated.

Through the branching of each of the lines 3a and 3b at the nodes 2a and 2b into three lines 3a, 3ab, 3ac and/or 3ba, 3bb, 3bc leading to the points 4a, 4b, 4c, 4d, 4e and 4f, rectangular areas with quadratic sub-areas divisible by three can be supplied uniformly with process gas.

In the present case, six sub-areas are supplied, that is, a format of 3×2 sub-areas, that is, a side length of 3:2.

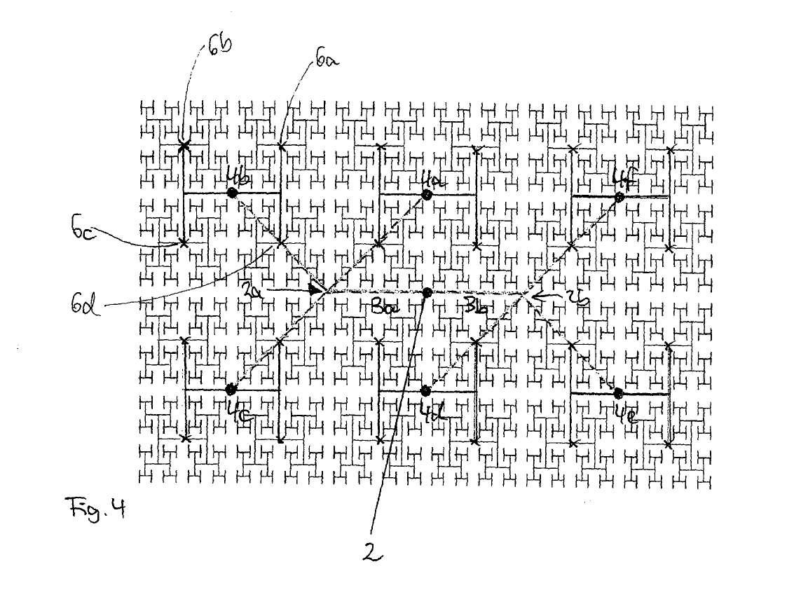

FIG. 4 shows an extension of the embodiment from FIG. 3 with a further branching level.

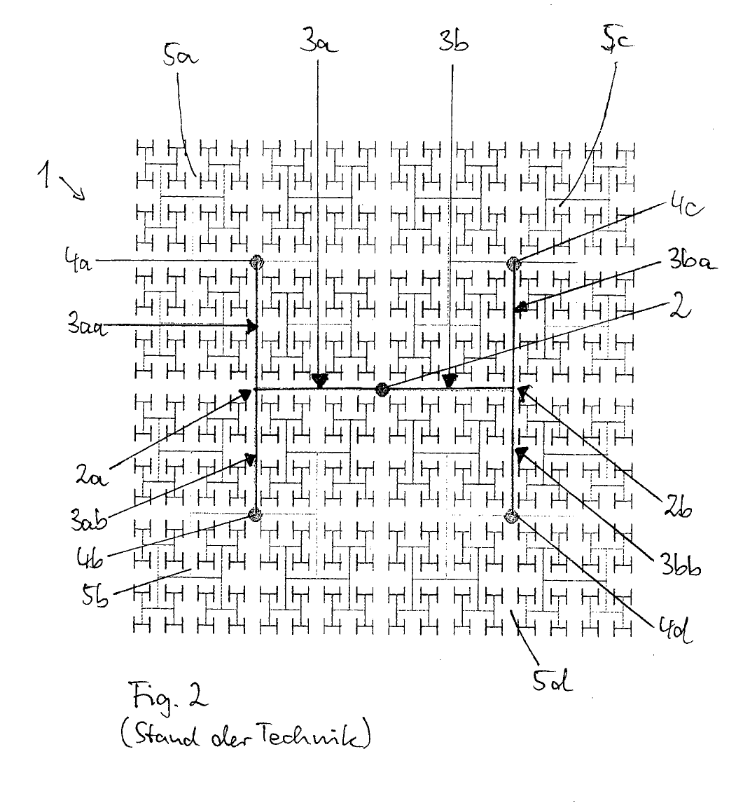

Proceeding from the feed point 2, the gas, as in FIG. 3, divides into two line sections 3a and 3b up to the nodes 2a or 2b. In the nodes 2a, 2b, lines 3a, 3b each undergo a 3-way division to the nodes 4a, 4b, 4c, 4d, 4e or 4f. The nodes 4a, 4b, 4c, 4d, 4e and 4f in turn form transitions to a next (third) line level. In this next line level, branching occurs at each of the nodes 4a, 4b, 4c, 4d, 4e and 4f into an H-shaped line structure, as shown in FIG. 2, as far as the outlet points marked with a cross (6a, 6b, 6c, 6d, etc.). Of the outlet points which are marked with a cross and which open from the third line level into the process chamber, only the outlet openings 6a, 6b, 6c and 6d belonging to the central node 4b are labeled.

The line structure shown is point-symmetrical with the feed point 2.

A structure with an aspect ratio of 1/b=3:1=6:2 might be realized, for example, by arranging a structure identical (or symmetrical) to FIG. 3 along the shorter side b of the area supplied by the gas inlet system in accordance with FIG. 3, an aspect ratio of 3:4 by arranging a structure identical (or symmetrical) to FIG. 3 along the longer side 1 of the area supplied by the gas inlet system in accordance with FIG. 3. The feed points 2 of the structures arranged next to each other would be supplied in the context of the invention by a feed point arranged centrally to the points 2.

The embodiment in accordance with FIG. 4 likewise yields a regular distribution of the openings 6a, 6b, 6c, 6d, etc. over a raster with a side length ratio of 6:4, (=3:2), but with an even finer, more homogeneous distribution of the gas over the total area.

In principle, all aspect ratios for an area to be supplied uniformly are feasible in the context of the invention, in which the side lengths of the raster split into integral units of length are divisible in arbitrary combinations by 2 and/or 3. This makes it possible in turn to coat substrates with completely new formats (3:2, 6:2, 3:4, 3:8 etc.) which, in certain circumstances, are simpler to handle or, for technical or esthetic reasons, are desirable relative to format ratios of 1:1 or even-numbered format ratios.

What is claimed is:

1. A coating installation, comprising a
a process chamber; and
a gas line system for supplying and/or letting out a gas into or out of the process chamber of the coating installation, wherein the gas line system includes at least one feed opening for feeding gas into the gas line system or for removing gas from the gas line system, at least two outlet openings for letting out the gas from the gas line system or for introducing the gas into the gas line system, and lines, which are each arranged between the at least one feed opening and the outlet openings, with the lines being formed such that the flow resistance of each line between the at least one feed opening and the outlet openings is essentially equally large,
wherein the gas line system has at least one branch point, at which a first line section opens into at least three second line sections connected to the first line section.

2. The coating installation according to claim 1, wherein the first line section opens into exactly three second line sections connected to the first line section.

3. The coating installation according to claim 1, wherein at least three outlet openings are connected to the at least one feed opening.

4. The coating installation according to claim 3, wherein at least three outlet openings are connected to exactly three outlet openings.

5. The coating installation according to claim 3, wherein at least three outlet openings are connected to N=3*2ⁿ outlet openings, where n is any positive integer.

6. The coating installation according to claim 1, wherein the lines between the feed opening and the outlet openings have the same length.

7. The coating installation according to claim 1, wherein the lines between the feed opening and the outlet openings each have the same number of branches.

8. The coating installation according to claim 1, wherein the lines run at least into two levels.

9. The coating installation according to claim 1, wherein the first line section runs from a first point to the branch point, and the at least three connecting second line sections, proceeding from the branch point, can form angles of 90° and/or 180° among themselves.

10. The coating installation according to claim 1, wherein the three line sections proceeding from the branch point can form angles of 45°, 135° or 225° with the first line section.

11. The coating installation according to claim 1, wherein the line system has a symmetrical structure.

12. The coating installation according to claim 1, wherein at least one line section is formed as a recess and/or depression in a plate.

13. The coating installation according to claim 1, wherein the first line section is formed as a recess and/or depression in a plate, and a connection is formed as a drill hole in the plate between the first line section and the at least three second line sections arranged on the side of the plate facing away from the first line section.

14. The coating installation according to claim 1, wherein the outlet openings are arranged as a regular raster over a total area such that the outlet openings each form centers for contiguous squares each of the same area, with the total area forming a rectangle with a non-even-numbered ratio V of the side lengths of ratios V of V=(3*2ⁿ)/(2^{m}), where n is any positive integer and m is also any positive integer.

15. The coating installation according to claim 1, wherein the number of outlet openings is three or an integral multiple of three.

16. The coating installation according to claim 1, wherein the gas line system is formed in the cover or as the cover of the process chamber of the coating installation.

17. The coating installation according to claim 1, wherein within the process chamber, means are arranged for the generation of a plasma.

18. The coating installation according to claim 1, wherein the outlet openings that open into the process chamber are formed as openings in a plasma-generating electrode.

19. A gas line system for supplying and/or letting out a gas into or out of a process chamber of a coating installation, comprising
at least one feed opening for feeding gas into the gas line system or for removing gas from the gas line system;
at least two outlet openings for letting out the gas from the gas line system or for introducing the gas into the gas line system, and,
has lines which are each arranged between at least the one feed opening and the outlet openings, with the lines being formed such that the flow resistance of the lines between each of the at least one feed opening and
the outlet openings is essentially equally large, wherein the gas line system has at least one branch point, at which a first line section opens into at least three second line sections connected to the first line section.
